(19) United States
(12) Patent Application Publication
(10) Pub. No.: US 2022/0335873 A1
(43) Pub. Date: Oct. 20, 2022

(54) DRIVING METHOD OF GATE DRIVING CIRCUIT, GATE DRIVING CIRCUIT AND DISPLAY DEVICE

(71) Applicants: WUHAN TIANMA MICRO-ELECTRONICS CO., LTD., Wuhan (CN); WUHAN TIANMA MICRO-ELECTRONICS CO., LTD. SHANGHAI BRANCH, Shanghai (CN)

(72) Inventors: Junting Ouyang, Shanghai (CN); Boquan LIN, Shanghai (CN); Kerui XI, Shanghai (CN); Xiangzi KONG, Shanghai (CN); Bojia LV, Shanghai (CN)

(73) Assignees: WUHAN TIANMA MICRO-ELECTRONICS CO., LTD., Wuhan (CN); WUHAN TIANMA MICRO-ELECTRONICS CO., LTD. SHANGHAI BRANCH, Shanghai (CN)

(21) Appl. No.: 17/811,123

(22) Filed: Jul. 7, 2022

Related U.S. Application Data
(63) Continuation of application No. 16/674,759, filed on Nov. 5, 2019.

(30) Foreign Application Priority Data
Jun. 28, 2019 (CN) 201910580321.6

(51) Int. Cl. G09G 3/20; G11C 19/28

(52) U.S. Cl. CPC G09G 3/20; G11C 19/28; G09G 2310/0286

(57) ABSTRACT

The present disclosure provides a driving method of a gate driving circuit. The driving method includes: outputting, by a plurality of shift register units of a shift register, signals sequentially, the plurality of shift register units being cascaded; determining, by a detection module, whether the plurality of shift register units has an abnormality according to one or more signals outputted from at least a part of the plurality of shift register units, and issuing a scan control command when it is determined that the plurality of shift register units has the abnormality; and controlling, by a scan control module, the shift register to perform forward scanning and reverse scanning under the scan control command.

### CROSS-REFERENCE TO RELATED APPLICATIONS

The present disclosure is a continuation of U.S. application Ser. No. 16/674,759, filed on Nov. 5, 2019, which claims priority under 35 U.S.C. § 119 to Chinese Patent Application No. 201910580321.6, filed on Jun. 28, 2019, the contents of which are incorporated herein by reference in entirety.

### TECHNICAL FIELD

The present disclosure relates to the technical field of display technologies, and in particular, to a driving method of a gate driving circuit, a gate driving circuit, and a display device.

### BACKGROUND

In order to drive a display panel to emit light normally, the display panel is provided with n cascaded shift register units, and the n shift register units are electrically connected to n gate lines in one-to-one correspondence. In one frame, a 1^{st} stage of shift register unit outputs a scanning signal to a 1^{st} gate line under driving of a frame start signal, and simultaneously outputs a shift control signal to a 2^{nd} stage of shift register unit. Then, a 2^{nd} stage of shift register unit outputs a scanning signal to a 2^{nd} gate line under driving of the shift control signal, and simultaneously outputs a shift control signal to a 3^{rd} stage of shift register unit, . . . , and so on, an n^{th} stage of shift register unit outputs a scanning signal to an n^{th} gate line under driving of the shift control signal. In this way, n rows of sub-pixels emit light sequentially, so that the display panel can display a complete image.

However, based on an operating principle of the shift register unit, if an i^{th} stage of shift register unit is damaged, a connection between the i^{th} stage of shift register unit and an (i+1)^{th} stage of shift register unit will break. As a result, the i^{th} to n^{th} stage of shift register units cannot output a scanning signal to the gate lines, and thus the (i+1)^{th} to n^{th} rows of sub-pixels cannot emit light, thereby causing a black screen in a partial area of the display panel. Especially for a display panel applied in a vehicle field, if a device such as a dashboard gives a black screen, there will be an unpredictable risk.

### SUMMARY

In view of this, the present disclosure provides driving methods of gate driving circuits, gate driving circuits, and display devices, which can timely detect an abnormal situation of the shift register units and then remedy the situation, thereby effectively ameliorating a black screen of the display panel.

In an aspect, an embodiment of the present disclosure provides a driving method of a gate driving circuit, including: outputting, by a plurality of shift register units of a shift register, signals sequentially, the plurality of shift register units being cascaded; determining, by a detection module, whether the plurality of shift register units has an abnormality according to one or more signals outputted from at least a part of the plurality of shift register units, and issuing a scan control command when it is determined that the plurality of shift register units has the abnormality; and controlling, by a scan control module, the shift register to perform forward scanning and reverse scanning under the scan control command.

In another aspect, an embodiment of the present disclosure provides a gate driving circuit a shift register, including a shift register, including a plurality of shift register units, the plurality of shift register units being cascaded and each of the plurality shift register units including a scanning signal terminal and a signal output terminal; a detection module electrically connected to one or more signal output terminals of at least a part of the plurality of shift register units; and a scan control module electrically connected to the detection module and the scanning signal terminal of each of the plurality of shift register units.

In still another aspect, an embodiment of the present disclosure provides a display device including the gate driving circuit described above.

### BRIEF DESCRIPTION OF DRAWINGS

In order to more clearly illustrate technical solutions in embodiments of the present disclosure, the accompanying drawings are briefly introduced as follows. It should be noted that the drawings described as follows are merely part of the embodiments of the present disclosure, other drawings can also be acquired by those skilled in the art without paying creative efforts.

FIG. 1 is a schematic diagram of a structure of a gate driving circuit according to an embodiment of the present disclosure:

FIG. 2 is a flowchart of a driving method according to an embodiment of the present disclosure;

FIG. 3 is a schematic diagram of another structure of a gate driving circuit according to an embodiment of the present disclosure;

FIG. 4 is a flowchart of another driving method according to an embodiment of the present disclosure;

FIG. 5 is a schematic diagram of still another structure of a gate driving circuit according to an embodiment of the present disclosure;

FIG. 6 is a schematic diagram of yet another structure of a gate driving circuit according to an embodiment of the present disclosure;

FIG. 7 is a flowchart of still another driving method according to an embodiment of the present disclosure;

FIG. 8 is a schematic diagram of yet another structure of a gate driving circuit according to an embodiment of the present disclosure;

FIG. 9 is a flowchart of yet another driving method according to an embodiment of the present disclosure;

FIG. 10 is a schematic diagram of a structure of switch units of a gate driving circuit according to an embodiment of the present disclosure; and

FIG. 11 is a schematic diagram of a structure of a display device according to an embodiment of the present disclosure.

### DESCRIPTION OF EMBODIMENTS

For better illustrating technical solutions of the present disclosure, embodiments of the present disclosure will be described in detail as follows with reference to the accompanying drawings.

It should be noted that the described embodiments are merely exemplary embodiments of the present disclosure. Other embodiments are expressly contemplated.

The terms used in the embodiments of the present disclosure are merely for the purpose of describing particular embodiments but not intended to limit the present disclosure. Unless otherwise noted in the context, the singular form expressions “a”, “an”, “the” and “said” used in the embodiments and appended claims of the present disclosure are also intended to represent plural form expressions thereof.

It should be understood that the term “and/or” used herein is merely an association relationship describing associated objects, indicating that there may be three relationships, for example. A and/or B may indicate three cases, i.e., A existing individually, A and B existing simultaneously, B existing individually. In addition, the character “/” herein generally indicates that the related objects before and after the character form an “or” relationship.

It should be understood that, although detection units and scan control units may be described using the terms of “first”, “second”, “third”, etc., in the embodiments of the present disclosure, the detection units and the scan control units will not be limited to these terms. These terms are merely used to distinguish detection units from one another and scan control units from one another. For example, without departing from the scope of the embodiments of the present disclosure, a first detection unit may also be referred to as a second detection unit, and similarly, a second detection unit may also be referred to as a first detection unit.

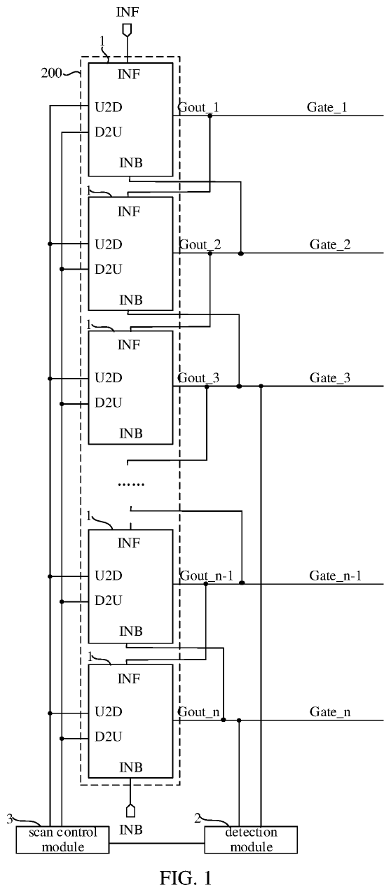

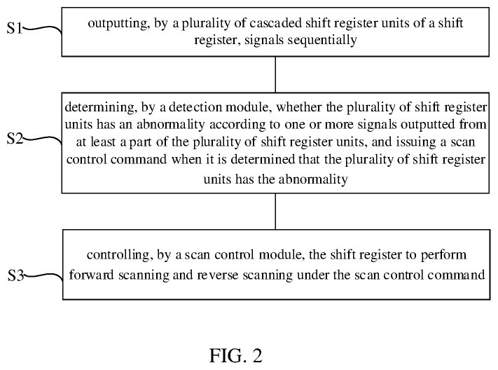

An embodiment of the present disclosure provides a driving method of a gate driving circuit. FIG. 1 is a schematic diagram of a structure of a gate driving circuit according to an embodiment of the present disclosure, and FIG. 2 is a flowchart of a driving method according to an embodiment of the present disclosure. With reference to FIG. 1 and FIG. 2, the driving method includes following steps.

At step S1, a plurality of cascaded shift register units 1 of a shift register 200 sequentially output signals.

At step S2, a detection module 2 determines whether the shift register units 1 have an abnormality according to the signals outputted from at least a part of the shift register units 1, and issues a scan control command when it is determined that the shift register units 1 have an abnormality.

At step S3, a scan control module 3 controls the shift register 200 to perform forward scanning and reverse scanning under the scan control command.

As an example, the shift register 200 includes n shift register units 1. The forward scanning means that the shift register units 1 perform scanning in a sequence from a 1^{st} stage to an n^{th} stage, and the reverse scanning means that the shift register units 1 perform scanning in a sequence from the n^{th} stage to the 1^{st} stage.

If the shift register units 1 have an abnormality, e.g., at least one of the plurality of shift register units 1 cannot output a signal, the detection module 2 detects the abnormality of the shift register units 1 according to signal output states of the shift register units 1. When an abnormality is determined, the scan control module 3 controls the shift register 200 to perform forward scanning and reverse scanning. For example, an i^{th} stage of shift register unit 1 has an abnormality. First, the scan control module 3 controls the shift register 200 to perform forward scanning. In combination with FIG. 1, the scan control module 3 provides a forward scanning signal U2D to each shift register unit 1, the 1^{st} stage of shift register unit 1 outputs a scanning signal to a 1^{st} gate line Gate_1 under driving of a frame start signal, and meanwhile, this scanning signal is transmitted to a forward shift control terminal INF of a 2^{nd} stage of shift register unit 1 to achieve downward shifting. Thereafter, the 2^{nd} stage of shift register unit 1 outputs a scanning signal to a 2^{nd} gate line Gate_2 under driving of a forward shift control signal, and meanwhile, this scanning signal is transmitted to a forward shift control terminal INF of a 3^{rd} stage of shift register unit 1, . . . , and so on. In this way, an (i−1)^{th} stage of shift register unit 1 outputs a scanning signal to an (i−1)^{th} gate line Gate_i−1 under driving of a forward shift control signal. During this scanning process, the 1^{st} stage of register unit 1 to the (i−1)^{th} stage of shift register unit 1 each output a scanning signal, and the i^{th} stage of shift register unit 1 to the n^{th} of shift register unit do not output a scanning signal since the i^{th} stage of shift register unit 1 has an abnormality and can neither output a signal nor perform the downward shifting. Then, the scan control module 3 controls the shift register 200 to perform reverse scanning. To be specific, the scan control module 3 provides a reverse scanning signal D2U to each shift register unit 1, the n^{th} stage of shift register unit 1 outputs a scanning signal to an n^{th} gate line Gate_n under driving of the frame start signal, and meanwhile, this scanning signal is transmitted to a reverse shift control terminal INB of an (n−1)^{th} stage of shift register unit 1 to achieve an upward shifting. Thereafter, the (n−1)^{th} stage of shift register unit 1 outputs a scanning signal to an (n−1)^{th} gate line Gate_n−1 under driving of a reverse shift control signal, and meanwhile, this scanning signal is transmitted to a reverse shift control terminal INB of an (n−2)^{th} stage of shift register unit 1, . . . , and so on. In this way, an (i+1)^{th} stage of shift register unit 1 outputs a scanning signal to an (i+1)^{th} gate line Gate_i+1 under driving of a reverse shift control signal. During this scanning process, the (i+1)^{th} stage of shift register unit 1 to the n^{th} stage of shift register unit 1 each output a scanning signal, and the 1^{st} stage of shift register unit 1 to the (i−1)^{th} stage of shift register unit 1 can neither output a scanning signal nor perform the upward shifting since the i^{th} stage of shift register unit 1 has as an abnormality. After scanning twice in such a way, the shift register units 1 other than the i^{th} stage of shift register unit 1 can normally output scanning signals to drive corresponding sub-pixels to emit light.

With the driving method provided by this embodiment of the present disclosure, on the one hand, the detection module 2 can perform timely and effective self-detection on an abnormal situation of the shift register units 1 during an operation process of the shift register units 1, thereby improving a detection efficiency; and on the other hand, when an abnormality of the shift register units 1 is determined, the shift register 200 can be controlled to perform forward scanning and reverse scanning, so that the shift register units 1 other than the abnormal shift register unit(s) 1 can normally output scanning signals, thereby allowing an image displayed by the display panel to approach a complete image and thus effectively ameliorating a large-area black screen.

In the vehicle field, the driving method can produce more significant effects. In an example, if shift register units 1 in a display panel of a device such as a dashboard have an abnormality during running of the vehicle, this driving method can detect the abnormality in time and remedy the abnormality quickly and effectively. In this way, it avoids a large risk caused by a sudden large-area black screen of the dashboard, thereby achieving safe driving.

In addition, the driving method provided by this embodiment of the present disclosure can be applied to an organic light-emitting diode (OLED) display panel or a liquid crystal display panel (LCD).

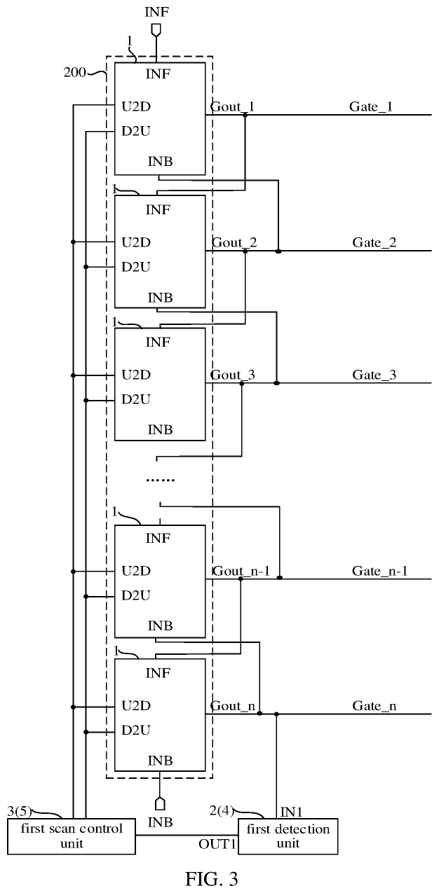

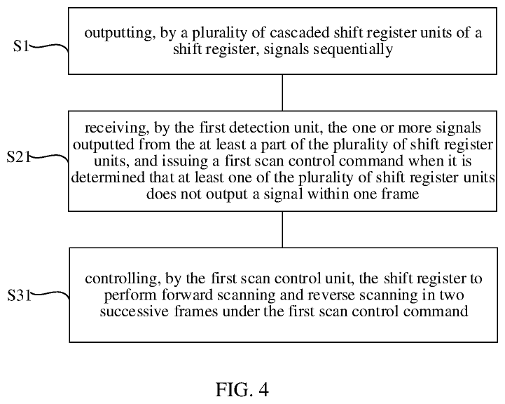

FIG. 3 is a schematic diagram of another structure of a gate driving circuit according to an embodiment of the present disclosure. With reference to FIG. 3, the detection module 2 includes a first detection unit 4, and the scan control module 3 includes a first scan control unit 5. FIG. 4 is a flowchart of another driving method according to an embodiment of the present disclosure. As shown in FIG. 4, the step S2 may include step S21.

At step S21, the first detection unit 4 receives signals outputted from at least a part of the shift register units 1, and issues a first scan control command when it is determined that at least one shift register unit 1 does not output a signal in one frame.

With further reference to FIG. 3, in an example, the first detection unit 4 receives a signal outputted from the n^{th} stage of shift register unit 1. During a process of the n shift register units 1 outputting signals, if all the shift register units 1 have no abnormality, the n^{th} stage of shift register unit 1 can normally output a signal in one frame, in which case the first detection unit 4 can receive a signal. If one stage of shift register unit 1 has an abnormality, the n^{th} stage of shift register unit 1 does not output a signal in one frame, in which case the first detection unit 4 cannot receive a signal. In this case, it is determined that the shift register units 1 have an abnormality, and then the first scan control command is issued.

The step S3 may include step S31.

At step S31, the first scan control unit 5 controls the shift register 200 to perform forward scanning and reverse scanning alternately in two successive frames under an action of the first scan control command.

For example, the i^{th} stage of shift register unit 1 has an abnormality. One driving cycle of the first scan control unit 5 includes two frames. In a first frame of the two frames, the scan control module 3 controls the shift register 200 to perform forward scanning, and the 1^{st} stage of shift register unit 1 to the (i−1)^{th} stage of shift register unit 1 each output a scanning signal while the (i−1)^{th} stage of shift register unit 1 to the n^{th} stage of shift register unit 1 do not output a signal. In a next frame, the scan control module 3 controls the shift register 200 to perform reverse scanning, and the (i+1)^{th} stage of shift register unit 1 to the n^{th} stage of shift register unit 1 each output a scanning signal while the 1^{st} stage of to the (i−1)^{th} stage of shift register unit 1 does not output a scanning signal.

In this driving method, two frames are taken as one driving cycle. In a first one of the two frames, a 1^{st} row of sub-pixels to an (i−1)^{th} row of sub-pixels are driven to emit light; and in the next frame, an (i+1)^{th} row of sub-pixels to an n^{th} row of sub-pixels are driven to emit light. For a user, the human eye can neither recognize if two parts of sub-pixels of the display panel rapidly alternately emit light in two successive frames nor recognize only one row of sub-pixels in the entire display area that do not emit light all the time. Therefore, the user still watches continuous and complete images and no black screen occurs when watching the screen, so that the user's view experience is improved.

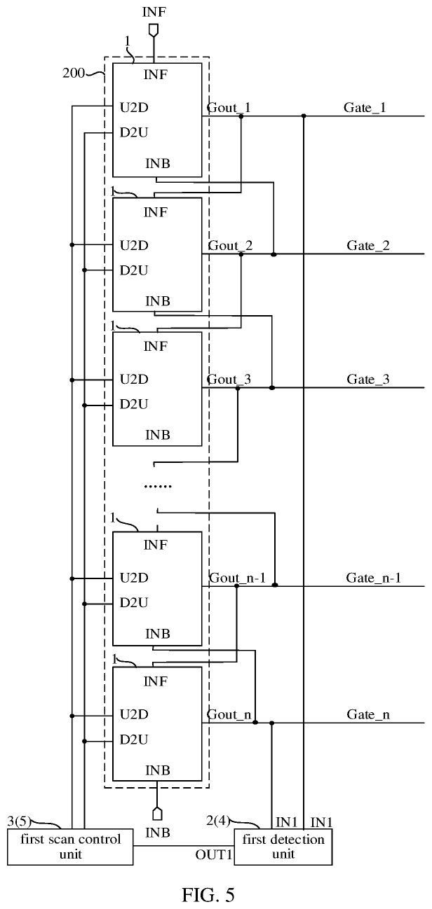

Further, the first detection unit 4 receives signals outputted by the 1^{st} stage of shift register unit 1 and the last stage of shift register unit 1, respectively. That is, as shown in FIG. 5, which is a schematic diagram of still another structure of a gate driving circuit according to an embodiment of the present disclosure, the first detection unit 4 is electrically connected to the 1^{st} stage of shift register unit 1 and the n^{th} stage of shift register unit 1. In this way, when the shift register 200 works normally, no matter forward scanning or reverse scanning is adopted, the first detection unit 4 can accurately detect whether the shift register units 1 have an abnormality, thereby improving a detection accuracy. When the shift register 200 performs forward scanning, the first detection unit 4 can determine whether the shift register units 1 have an abnormality based on whether the n^{th} stage of shift register unit 1 outputs a signal in one frame. When the shift register 200 performs reverse scanning, the first detection unit 4 can determine whether the shift register units 1 have an abnormality based on whether the 1^{st} stage of shift register unit 1 outputs a signal in one frame.

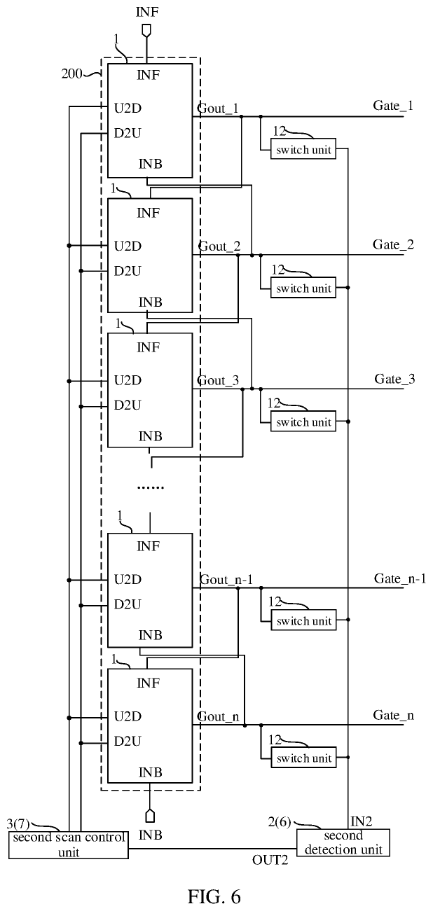

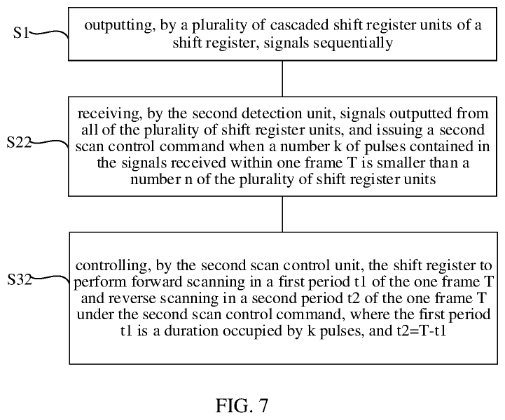

FIG. 6 is a schematic diagram of yet another structure of a gate driving circuit according to an embodiment of the present disclosure. With reference to FIG. 6, in an embodiment, the detection module 2 includes a second detection unit 6, and the scan control module 3 includes a second scan control unit 7. FIG. 7 is a flowchart of still another driving method according to an embodiment of the present disclosure. As shown in FIG. 7, the step S2 may include step S22.

At a step S22, the second detection unit 6 receives signals outputted by all shift register units 1 and issues a second scan control command when a number k of pulses contained in the signals received in one frame T is smaller than a number n of the shift register units 1.

The second detection unit 6 receives signals outputted from all shift register units 1. If no shift register unit 1 has an abnormality, each shift register unit 1 outputs a pulse signal, and the number of pulses in signals received by the second detection unit 6 in one frame T is n. If a (k+1)^{th} stage of shift register unit 1 has an abnormality, the 1^{st} stage of shift register unit 1 to a k^{th} stage of shift register unit 1 each output a signal while the (k+1)^{th} stage of shift register unit 1 to the n^{th} stage of shift register unit 1 do not output a signal. In this case, the number of pulses in signals received by the second detection unit 6 is k. Therefore, according to the number of pulses in signals received by the second detection unit 6, it can be determined whether the shift register units 1 have an abnormality, and also which stage of shift register unit 1 has an abnormality can be determined.

The step S3 may include step S32.

At step S32, the second scan control unit 7 controls the shift register 200 to perform forward scanning and reverse scanning in a first period t1 and in a second period 2 of one frame T under an action of the second scan control command. Here, the first period t1 is a duration occupied by k pulses, and t2=T−t1.

When the (k+1)^{th} stage of shift register unit 1 has an abnormality, one driving cycle of the second scan control unit 7 is one frame. First, the scan control module 3 controls the shift register 200 to perform forward scanning in the first period t1, so as to drive the 1^{st} stage of shift register unit 1 to the k^{th} stage of shift register unit 1 to sequentially output scanning signals, and the forward scanning stops after the k^{th} stage of shift register unit 1 outputs a scanning signal. Then, the scan control module 3 controls the shift register 200 to perform reverse scanning in the second period t2, so as to control a (k+2)^{th} stage of shift register unit 1 to the n^{th} stage of shift register unit 1 to output scanning signals, and the reverse scanning stops after the (k+2)^{th} stage of shift register unit 1 outputs a scanning signal.

This driving method can determine which stage of shift register unit 1 has an abnormality, and then control the shift register 200 to perform forward scanning and reverse scanning in one frame, thereby shortening the scanning cycle. Moreover, accurate determination of a position(s) of the abnormal shift register unit(s) 1 can facilitate subsequent remedy for the shift register units 1 in the display panel, thereby significantly shortening troubleshooting and remedy time for the shift register units 1.

Further, before the second detection unit 6 detects the signals output from the shift register units 1, the shift register 200 performs scanning in a first direction. In the first period t1, the shift register 200 performs scanning in the first direction; and in the second period t2, the shift register 200 performs scanning in a second direction. Here, the first direction is a forward direction, and the second direction is a reverse direction; or the first direction is a reverse direction, and the second direction is a forward direction.

Taking the first direction being the forward direction as an example, when the shift register 200 performs forward scanning and sequentially outputs scanning signals, if an abnormality of the (k+1)^{th} stage of shift register unit 1 is determined, the shift register 200 is controlled to perform forward scanning in the first period t1 to drive the first k stages of shift register units 1 to normally output signals, and the shift register 200 is controlled to perform reverse scanning in the second period t2 to drive the next (n−k−1) stages of shift register units 1 to normally output signals. In this way, the abnormal (k+1)^{th} stage of shift register unit 1 does not output a signal in one frame, thereby further achieving integrity of an image. In an embodiment, only the abnormal (k+1)^{th} stage of shift register unit 1 does not output a signal in one frame.

In an example, signals outputted from a plurality of shift register unit 1 are transmitted to the second detection unit 6 via one detection line in time division, while only a signal outputted from one shift register unit 1 is transmitted to the detection line at one time. Such a signal transmission mode can allow the signals outputted from the shift register units 1 to be sequentially transmitted to the detection line in time division, thereby avoiding introduction of a plurality of signals in a same period and thus improving the detection accuracy.

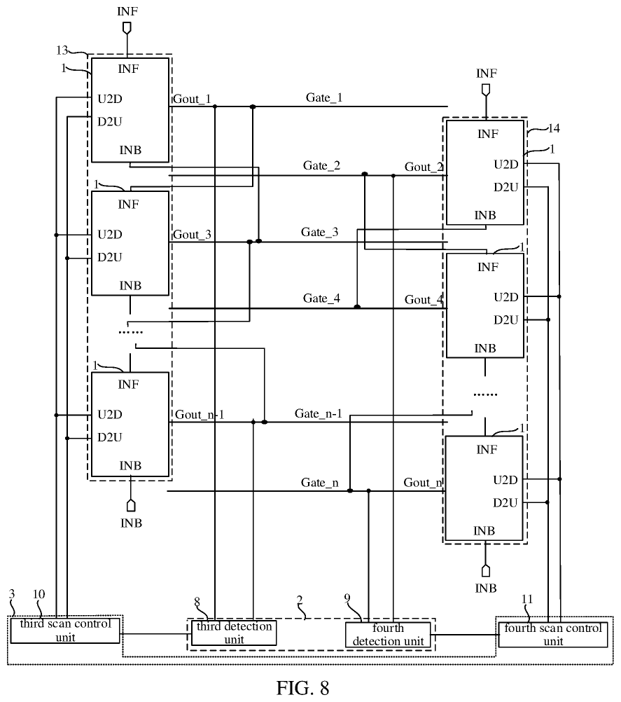

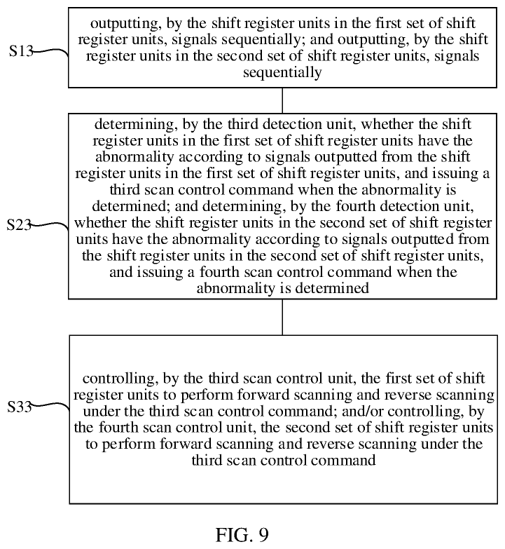

FIG. 8 is a schematic diagram of yet another structure of a gate driving circuit according to an embodiment of the present disclosure. In an embodiment, as shown in FIG. 8, for the shift register 200, the shift register units corresponding to odd-numbered rows of gate lines constitute a first set 13 of shift register units, and the shift register units corresponding to even-numbered rows of gate lines constitute a second set 14 of shift register unit. The detection module 2 includes a third detection unit 8 and a fourth detection unit 9, and the scan control module 3 includes a third scan control unit 10 and a fourth scan control unit 11. FIG. 9 is a flowchart of yet another driving method according to an embodiment of the present disclosure. As shown in FIG. 9, the step S1 may include step S13.

At step S13, the shift register units 1 in the first set 13 of shift register units sequentially output signals, and the shift register units 1 in the second set 14 of shift register units sequentially output signals.

The step S2 may include step S23.

At step S23, the third detection unit determines whether the shift register units 1 in the first set 13 of shift register units have an abnormality according to the signals outputted from the shift register units 1 in the first set 14 of shift register units, and issues a third scan control command when an abnormality is determined; and the fourth detection unit determines whether the shift register units 1 in the second set 14 of shift register units have an abnormality according to the signals outputted from the shift register units 1 in the second set 14 of shift register units, and issues a fourth scan control command when an abnormality is determined.

The step S3 may include step S33.

At step S33, the third scan control unit 10 controls the first set 13 of shift register units to perform forward scanning and reverse scanning under the third scan control command, and/or the fourth scan control unit 11 controls the second set 14 of shift register units to perform forward scanning and reverse scanning under the fourth scan control command.

For example, the shift register units 1 in the first set 13 of shift register units have an abnormality. If multiple shift register units 1 in the first set 13 of shift register units are abnormal, the multiple abnormal shift register units 1 will not have an influence on scanning of the even-numbered rows of shift register units 1. In this case, at least half of the shift register units 1 can still work normally and a part of the odd-numbered rows of sub-pixels corresponding to the multiple abnormal shift register units 1 do not emit light. This can reduce an influence of the abnormal shift register units 1 on the entire display image.

An embodiment of the present disclosure further provides a gate driving circuit. With further reference to FIG. 1, the gate driving circuit includes a shift register 200, a detection module 2, and a scan control module 3. The shift register 200 includes a plurality of cascaded shift register units 1.

Each shift register unit 1 includes scanning signal terminals and a signal output terminal Gout, and the scanning signal terminals include a forward scanning signal terminal U2D and an inverse scanning signal terminal D2U. The shift register units 1 sequentially output scanning signals. The detection module 2 is electrically connected to the signal output terminals Gout of at least a part of the shift register units 1. The detection module 2 is configured to determine whether the shift register units 1 have an abnormality according to the signals output from the at least a part of the shift register units 1, and issue a scan control command when it is determined that the shift register units 1 have an abnormality. The scan control module 3 is electrically connected to the detection module 2 and the scanning signal terminals of each shift register unit 1. The scan control module 3 controls the shift register 200 to perform forward scanning and reverse scanning under the scan control command.

The detection module 2 detects an abnormal situation of the shift register units 1 according to a signal output state of the shift register units 1. For example, the i^{th} stage of shift register unit 1 has an abnormality. First, the scan control module 3 controls the shift register 200 to perform forward scanning, a forward scanning signal is inputted to the forward scanning signal terminal U2D of the shift register unit 1, and the 1^{st} stage of shift register unit 1 to the (i−1)^{th} stage of shift register unit 1 are controlled to output scanning signals. Then, the scan control module 3 controls the shift register units 1 to perform reverse scanning, a reverse scanning signal is inputted to the reverse scanning signal terminal D2U of the shift register unit 1, and the (i+1)^{th} stage of shift register unit 1 to the n^{th} stage of shift register unit 1 are controlled to output scanning signals. After scanning twice in such a way, the shift register units 1 other than the i^{th} stage of shift register unit 1 can normally output scanning signals to drive corresponding sub-pixels to emit light.

An operating principle of forward scanning and reverse scanning of the shift register 200 has been described in the above embodiments.

It can be seen that, with the gate driving circuit provided by this embodiment of the present disclosure, on the one hand, the present disclosure can perform timely and effective self-detection on an abnormal situation of the shift register units 1, and on the other hand, when an abnormality of the shift register units 1 is determined, the shift register 200 can be controlled to perform forward scanning and reverse scanning, so that the shift register units 1 other than the abnormal shift register unit(s) 1 can normally output scanning signals, thereby allowing an image displayed by the display panel to approach a complete image and thus effectively ameliorating a black screen.

In an embodiment, with further reference to FIG. 3 and FIG. 5, the detection module 2 includes a first detection unit 4, and the first detection unit 4 includes a first output terminal OUT1 and m first input terminals IN1. The m first input terminals IN1 are electrically connected to signal output terminals Gout of m shift register units 1 in one-to-one correspondence, where 1≤m≤n and n is a number of shift register units 1. The first detection unit 4 is configured to receive signals outputted from at least a part of the shift register units 1, and issue a first scan control command when it is determined that at least one shift register unit 1 does not output a signal within one frame.

The scan control module 3 includes a first scan control unit 5, and the first scan control unit 5 is electrically connected to the first output terminal OUT1 and the at least one scanning signal terminal of each shift register unit 1. The first scan control unit 5 is configured to control the shift register 200 to perform forward scanning and reverse scanning alternately in two successive frames under the action of the first scan control command.

When the first detection unit 4 detects that the shift register units 1 have an abnormality, the first scan control unit 5 controls the shift register 200 to perform forward scanning and reverse scanning. In two successive frames, the 1^{st} row of sub-pixels to the (i−1)^{th} row of sub-pixels are driven to emit light and the (i+1)^{th} row of sub-pixels to the n^{th} row of sub-pixels are driven to emit light, respectively. For a user, the human eye can neither recognize if two parts of sub-pixels alternately emit light in two successive frames nor recognize one row of sub-pixels that do not emit light all the time. Therefore, the user can still watch continuous complete images and no black screen occurs when viewing the screen.

Further, please refer to FIG. 5, in which m=2. Two first input terminals IN1 are electrically connected to the signal output terminal Gout of the 1^{st} stage of shift register unit 1 and the signal output terminal Gout of the last stage of shift register unit 1, respectively. In this way, when the shift register 200 works normally, the first detection unit 4 can accurately detect whether the shift register units 1 have an abnormality no matter forward scanning or reverse scanning is performed, thereby improving the detection accuracy.

In an embodiment, with reference to FIG. 6, the detection module 2 includes a second detection unit 6. The second detection unit 6 includes a second input terminal IN2 and a second output terminal OUT2. The signal output terminal Gout of each shift register unit 1 is electrically connected to the second input terminal IN2 via a switch unit 12. The second detection unit 6 is configured to receive the signals outputted from all shift register units 1. When a number k of pulses of signals received in one frame T is smaller than a number n of shift register units 1, the second scan control command is issued.

The scan control module 3 includes a second scan control unit 7, and the second scan control unit 7 is electrically connected to the second output terminal OUT2 and the scanning signal terminals (the forward scanning signal terminal U2D and the reverse scanning signal terminal D2U) of each shift register unit 1. The second scan control unit 7 is configured to control the shift register 200 to perform forward scanning and reverse scanning in a first period t1 and in a second period t2 of one frame T under the action of the second scan control command. Here, the first period t1 a duration occupied by k pulses, and t2=T−t1.

The second detection unit 6 can determine which stage of shift register unit 1 has an abnormality according to the number of pulses of received signals, and then the shift register 200 is controlled to perform forward scanning and reverse scanning in one frame, thereby shortening the scanning period. Moreover, accurate determination of the abnormal shift register unit 1 is also beneficial to subsequent remedy for the shift register unit 1, which significantly shortens the troubleshooting and remedy time for the shift register unit 1.

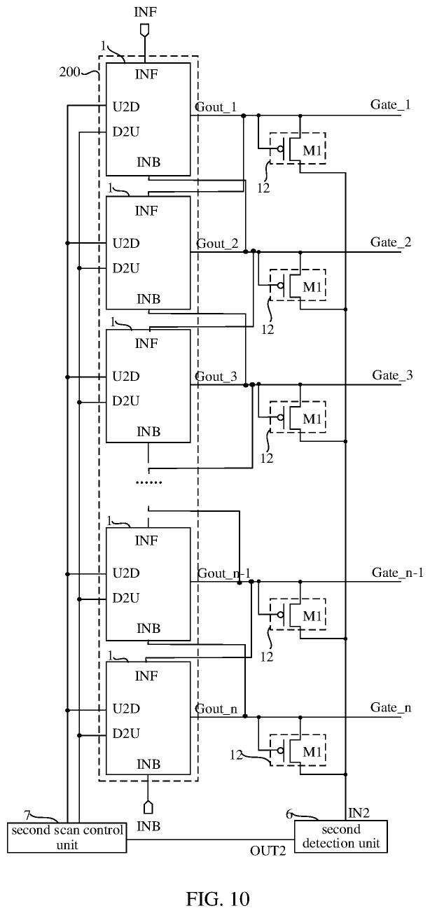

FIG. 10 is a schematic diagram of a structure of switch units of a gate driving circuit according to an embodiment of the present disclosure. In an embodiment, with reference to FIG. 10, the switch unit 12 includes a thin film transistor M1. The thin film transistor M1 is turned on when the scan register unit 1 electrically connected thereto outputs a scanning signal. In some embodiments, thin film transistor M1 is turned on only when the scan register unit 1 electrically connected thereto outputs a scanning signal, and is not turned on at other moments. This can allow the signals outputted from the shift register units 1 to be sequentially transmitted to the detection line in a time-division manner, thereby avoiding introduction of a plurality of signals in a same period and thus improving the detection accuracy.

Further, with further reference to FIG. 10, the thin film transistor M1 includes a gate electrode and a first electrode that are electrically connected to the signal output terminal Gout of the corresponding shift register unit 1, and the thin film transistor M1 also includes a second electrode that is electrically connected to the second input terminal IN2. When a certain stage of shift register unit 1 outputs a scanning signal, the thin film transistor M1 is turned on under an action of the scanning signal, and the scanning signal is transmitted to the second detection unit 6 via the turned-on thin film transistor M1. Since only one shift register unit 1 outputs a scanning signal at one time, the signal of only one shift register unit 1 is transmitted to the second detection unit 6 at one time. In this way, it avoids signal crosstalk, thereby improving a signal transmission accuracy.

In an embodiment, with further reference to FIG. 8, for the shift register 200, the shift register units 1 corresponding to odd-numbered rows of gate lines Gate constitute a first set 13 of shift register units, and the shift register units 1 corresponding to the even-numbered rows of gate lines Gate constitute a second set 14 of shift register units.

The detection module 2 includes a third detection unit and a fourth detection unit. The third detection unit is electrically connected to the signal output terminals Gout of at least a part of the shift register units 1 in the first set 13 of shift register units, and the fourth detection unit is electrically connected to the signal output terminals Gout of at least a part of the shift register units 1 in the second set 14 of shift register units. The third detection unit determines whether the shift register units 1 in the first set 13 of shift register units have an abnormality according to the signals outputted from the shift register units 1 in the first set 13 of shift register units, and issues a third scan control command when an abnormality is determined. The fourth detection unit determines whether the shift register units 1 in the second set 14 of shift register units have an abnormality according to the signals outputted from the shift register units 1 in the second set 14 of shift register units, and issues a fourth scan control command when an abnormality is determined.

The scan control module 3 includes a third scan control unit 10 and a fourth scan control unit 11. The third scan control unit 10 is electrically connected to the third detection unit and the scanning signal terminals (the forward scanning signal terminal U2D and the reverse scanning signal terminal D2U) of each shift register unit 1 in the first set 13 of shift register units. The fourth scan control unit 11 is electrically connected to the fourth detection unit and the scanning signal terminals (the forward scanning signal terminal U2D and the reverse scanning signal terminal D2U) of each shift register unit 1 in the second set 14 of shift register units. The third scan control unit 10 is configured to control the first set 13 of shift register units to perform forward scanning and reverse scanning under an action of the third scan control command, and/or the fourth scan control unit 11 is configured to control the second set 14 of shift register units to perform forward scanning and reverse scanning under an action of the fourth scan control command.

For example, the shift register units 1 in the first set 13 of shift register units may have an abnormality. If multiple shift register units 1 in the first set 13 of shift register units are abnormal, the abnormal shift register units 1 will not have an influence on scanning of the second set 14 of shift register units 1. In this case, at least half of the shift register units 1 can still work normally, thereby reducing an influence of the multiple abnormal shift register units 1 on the entire display image.

Further, with further reference to FIG. 8, the first set 13 of shift register units and the second set 14 of shift register units are respectively arranged at two sides of the gate line Gate in a direction in which the gate lines extend. The shift register units 1 are arranged in a bezel area of the display panel. Therefore, by arranging the first set 13 of shift register units and the second set 14 of shift register units at two sides of the gate lines Gate, the bezel area can be rationally designed. In this way, widths of bezel at two sides of the gate lines Gate can be balanced, thereby optimizing an appearance of the display panel.

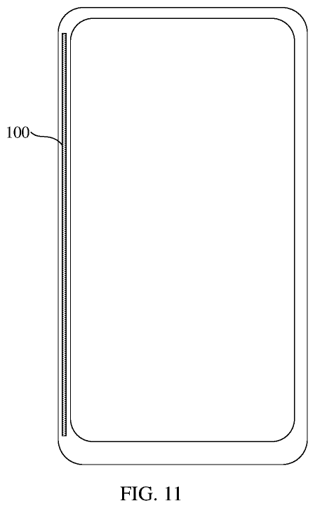

An embodiment of the present disclosure further provides a display device. FIG. 11 is a schematic diagram of a structure of a display device according to an embodiment of the present disclosure. As shown in FIG. 11, the display device includes the gate driving circuit 100 described above. The structure of the gate driving circuit 100 has been described in detail in the above embodiments, and will not be further described herein. The display device shown in FIG. 11 is merely illustrative, and the display device may be any electronic device having a display function such as a cellphone, a tablet computer, a notebook computer, an electronic paper book, or a television set.

The display device provided by this embodiment of the present disclosure includes the gate driving circuit 100 described above. Therefore, with the display device, on the one hand, the present disclosure can perform timely and effective self-detection on an abnormal situation of the shift register units 1; and on the other hand, the present disclosure can perform remedying when the shift register units 1 have an abnormality, so that the shift register units 1 other than the abnormal shift register unit 1 can normally output scanning signals, thereby allowing an image displayed by the display panel to approach a complete image and thus effectively ameliorating a black screen.

The above-described embodiments are merely preferred embodiments of the present disclosure and are not intended to limit the present disclosure. Any modifications, equivalent substitutions and improvements made within the principle of the present disclosure shall fall into the protection scope of the present disclosure.

The above-described embodiments are merely for illustrating the present disclosure but not intended to provide any limitation. Although the present disclosure has been described in detail with reference to the above-described embodiments, it should be understood by those skilled in the art that, it is still possible to modify the technical solutions described in the above embodiments or to equivalently replace some or all of the technical features therein, but these modifications or replacements do not cause the essence of corresponding technical solutions to depart from the scope of the present disclosure.

1.-19. (canceled)

20. A driving method of a gate driving circuit, comprising:
outputting, by a plurality of shift register units of a shift register, signals sequentially, the plurality of shift register units being cascaded;
determining, by a detection module, whether the plurality of shift register units has an abnormal shift register unit according to one or more signals outputted from at least a part of the plurality of shift register units, and issuing a scan control command upon determining that the plurality of shift register units has the abnormal shift register unit; and
controlling, by a scan control module, the shift register to perform both forward scanning and reverse scanning during one driving cycle under the scan control command.

21. The method according to claim 20, wherein said controlling, by a scan control module, the shift register to perform both forward scanning and reverse scanning within one driving cycle under the scan control command comprises:
outputting during the forward scanning, by each shift register unit of the plurality of shift register units previous to the abnormal shift register unit, a scanning signal; and
outputting during the reverse scanning, by each shift register unit of the plurality of shift register units subsequent to the abnormal shift register unit, a scanning signal.

22. The method according to claim 20, wherein the detection module comprises a first detection structure, and the scan control module comprises a first scan control structure,
wherein said determining, by the detection module, whether the plurality of shift register units has the abnormal shift register unit according to the one or more signals outputted from the at least a part of the plurality of shift register units and issuing the scan control command upon determining that the plurality of shift register units has the abnormal shift register unit comprises: receiving, by the first detection structure: receiving, by the first detection structure, signals outputted from all of the plurality of shift register units, and issuing a first scan control command signal when k is smaller than n, where n denotes a number of the plurality of shift register units of the shift register, and k denotes a number of the plurality of pulses contained by the signals received within one frame T, and
wherein said controlling, by the scan control module, the shift register to perform both forward scanning and reverse scanning during one driving cycle under the scan control command comprises: controlling, by the first scan control structure, the shift register to perform forward scanning in a first period t1 of the one frame T and reverse scanning in a second period t2 of the one frame T under the first scan control command signal, where the first period t1 is a duration occupied by k pulses, and t2=T−t1.

23. The method according to claim 22, wherein the shift register performs scanning in a first direction before the first detection structure receives the signals outputted from the plurality of shift register units;
the shift register performs scanning in the first direction in the first period t1, and the shift register performs scanning in a second direction in the second period t2; and the first direction is a forward direction and the second direction is a reverse direction, or the first direction is a reverse direction and the second direction is a forward direction.

24. The method according to claim 23, wherein said receiving, by the first detection structure, the signals outputted from all of the plurality of shift register units comprises: receiving, by the first detection structure, the signals outputted from all of the plurality of shift register units via one detection line in time division, wherein only a signal outputted from one of the plurality of shift register units is transmitted to the detection line at one time.

25. The method according to claim 20, wherein
shift register units of the plurality of shift register units electrically connected to odd-numbered rows of gate lines constitute a first set of shift register units, and shift register units of the plurality of shift register units electrically connected even-numbered rows of gate lines constitute a second set of shift register units;
the detection module comprises a second detection structure and a third detection structure;
the scan control module comprises a second scan control structure and a third scan control structure;
said outputting, by the plurality of cascaded shift register units of the shift register, signals sequentially comprises: outputting, by the shift register units in the first set of shift register units, signals sequentially; and outputting, by the shift register units in the second set of shift register units, signals sequentially;
said determining, by the detection module, whether the plurality of shift register units has the abnormal shift register unit according to the one or more signals outputted from the at least a part of the plurality of shift register units and issuing the scan control command upon determining that the plurality of shift register units has the abnormal shift register unit comprises: determining, by the second detection structure, whether the shift register units in the first set of shift register units have the abnormal shift register unit according to signals outputted from the shift register units in the first set of shift register units, and issuing a second scan control command signal upon determining that the shift register units in the first set of shift register units have the abnormal shift register unit; and determining, by the second detection structure, whether the shift register units in the second set of shift register units have the abnormal shift register unit according to signals outputted from the shift register units in the second set of shift register units, and issuing a third scan control command signal upon determining that the shift register units in the second set of shift register units have the abnormal shift register unit, and
said controlling, by the scan control module, the shift register to perform both forward scanning and reverse scanning during one driving cycle under the scan control command comprises: controlling, by the second scan control structure, the first set of shift register units to perform both forward scanning and reverse scanning during one driving cycle under the second scan control command signal; and/or controlling, by the third scan control structure, the second set of shift register units to perform both forward scanning and reverse scanning during one driving cycle under the third scan control command signal.

26. A gate driving circuit, comprising:
a shift register, comprising a plurality of shift register units, the plurality of shift register units being cascaded and each of the plurality shift register units comprising a scanning signal terminal and a signal output terminal;
a detection module electrically connected to one or more signal output terminals of at least a part of the plurality of shift register units; and
a scan control module electrically connected to the detection module and the scanning signal terminal of each of the plurality of shift register units.

27. The gate driving circuit according to claim 26,
wherein the detection module comprises a first detection structure, the first detection structure comprises a first input terminal and a first output terminal, and the signal output terminal of each of the plurality of shift register units is electrically connected to the first input terminal via a switch unit, and
wherein the scan control module comprises a first scan control structure electrically connected to the first output terminal and the scanning signal terminal of each of the plurality of shift register units.

28. The gate driving circuit according to claim 27, wherein the switch unit comprises a thin film transistor, and the thin film transistor is turned on only when a shift register unit of the plurality of shift register units electrically connected to the thin film transistor outputs a signal.

29. The gate driving circuit according to claim 28, wherein the thin film transistor comprises a gate electrode, a first electrode and a second electrode, both the gate electrode and the first electrode being electrically connected to the signal output terminal of a corresponding shift register unit, and the second electrode being electrically connected to the second input terminal.

30. The gate driving circuit according to claim 26, wherein shift register units of the plurality of shift register units corresponding to odd-numbered rows of gate lines constitute a first set of shift register units, and shift register units of the plurality of shift register units corresponding to even-numbered rows of gate lines constitute a second set of shift register units;
the detection module comprises a second detection structure and a third detection structure, the second detection structure is electrically connected to one or more signal output terminals of at least a part of the shift register units in the first set of shift register units, and the third detection structure is electrically connected to one or more signal output terminals of at least a part of the shift register units in the second set of shift register units, and
wherein the scan control module comprises a second scan control structure and a third scan control structure, the second scan control structure is electrically connected to the second detection structure and the scanning signal terminal of each shift register unit in the first set of shift register units, and the third scan control structure is electrically connected to the third detection structure and the scanning signal terminal of each shift register unit in the second set of shift register units.

31. The gate driving circuit according to claim 30, wherein the first set of shift register units and the second set of shift register units are respectively arranged at two sides of the gate lines in a direction in which the gate lines extend.

32. A display device, comprising:
a gate driving circuit, comprising:
a shift register, comprising a plurality of shift register units, the plurality of shift register units being cascaded and each of the plurality shift register units comprising a scanning signal terminal and a signal output terminal;
a detection module electrically connected to one or more signal output terminals of at least a part of the plurality of shift register units; and
a scan control module electrically connected to the detection module and the scanning signal terminal of each of the plurality of shift register units.

33. The display device according to claim 32,
wherein the detection module comprises a first detection structure, the first detection structure comprises a first input terminal and a first output terminal, and the signal output terminal of each of the plurality of shift register units is electrically connected to the first input terminal via a switch unit, and
wherein the scan control module comprises a first scan control structure electrically connected to the first output terminal and the scanning signal terminal of each of the plurality of shift register units.

34. The display device according to claim 32,
wherein shift register units of the plurality of shift register units corresponding to odd-numbered rows of gate lines constitute a first set of shift register units, and shift register units of the plurality of shift register units corresponding to even-numbered rows of gate lines constitute a second set of shift register units;
the detection module comprises a second detection structure and a third detection structure, the second detection structure is electrically connected to one or more signal output terminals of at least a part of the shift register units in the first set of shift register units, and the third detection structure is electrically connected to one or more signal output terminals of at least a part of the shift register units in the second set of shift register units, and
wherein the scan control module comprises a second scan control structure and a third scan control structure, the second scan control structure is electrically connected to the second detection structure and the scanning signal terminal of each shift register unit in the first set of shift register units, and the third scan control structure is electrically connected to the third detection structure and the scanning signal terminal of each shift register unit in the second set of shift register units.
